(19) United States
(12) Patent Application Publication
(10) Pub. No.: US 2026/0107388 A1
(43) Pub. Date: Apr. 16, 2026

(54) CIRCUIT MODULE

(71) Applicant: Murata Manufacturing Co., Ltd., Nagaokakyo-shi (JP)

(72) Inventor: Mayu SUZUKI, Nagaokakyo-shi (JP)

(21) Appl. No.: 19/407,800

(22) Filed: Dec. 3, 2025

Related U.S. Application Data
(63) Continuation of application No. PCT/JP2024/014999, filed on Apr. 15, 2024.

(30) Foreign Application Priority Data
Jun. 14, 2023 (JP) 2023-097426

(51) Int. Cl. H05K 1/181; H05K 1/02

(52) U.S. Cl. CPC H05K 1/181; H05K 1/0296; H05K 2201/1003

(57) ABSTRACT

A circuit module includes a circuit board that includes a circuit board body and a conductor, the circuit board body including a first upper end surface and a first lower end surface situated side by side in an upward direction and a downward direction, the conductor being provided at the first upper end surface, an insulator at the first upper end surface, a first electrode including a second upper end surface, a second lower end surface, and a first side surface, and electrically connected to the conductor, the second upper end surface and the second lower end surface being situated side by side in the upward direction and the downward direction, the first side surface being connected to the second upper end surface, and an electronic component including an electronic component body and a second electrode and located above the insulator. The second upper end surface is covered by the insulator, and the second electrode is electrically connected to the first electrode as a result of at least a portion of the first side surface being exposed from the insulator.

### CROSS REFERENCE TO RELATED APPLICATIONS

This application claims the benefit of priority to Japanese Patent Application No. 2023-097426 filed on Jun. 14, 2023 and is a Continuation Application of PCT Application No. PCT/JP2024/014999 filed on Apr. 15, 2024. The entire contents of each application are hereby incorporated herein by reference.

### BACKGROUND OF THE INVENTION

### 1. Field of the Invention

The present invention relates to circuit modules.

### 2. Description of the Related Art

As an invention related to a circuit module of a related art, for example, a circuit module described in Japanese Unexamined Patent Application Publication No. 2022-189354 is known. The circuit module described in Japanese Unexamined Patent Application Publication No. 2022-189354 includes a board module that has an upper main surface, an electronic component that is disposed above the board module, and a bonding adhesive that fixes the electronic component to the upper main surface of the board module. The electronic component includes a first electrode. The board module includes a second electrode. The first electrode is electrically connected to the second electrode by solder.

In manufacturing the circuit module described in Japanese Unexamined Patent Application Publication No. 2022-189354, a step of exposing the second electrode from the upper main surface of the board module by grinding the upper main surface of the board module (a grinding step) is sometimes included. In this case, the productivity of the circuit module described in Japanese Unexamined Patent Application Publication No. 2022-189354 is decreased. Therefore, in the field of the circuit module described in Japanese Unexamined Patent Application Publication No. 2022-189354, there is a demand to eliminate the grinding step at the time of the manufacturing.

### SUMMARY OF THE INVENTION

Accordingly, example embodiments of the present invention provide circuit modules each able to eliminate a grinding step at the time of manufacturing.

A circuit module according to an example embodiment of the present invention includes a circuit board including a circuit board body and a conductor, the circuit board body including a first upper end surface and a first lower end surface located side by side in an upward direction and a downward direction, the conductor being located at the first upper end surface, an insulator at the first upper end surface, a first electrode including a second upper end surface, a second lower end surface, and a first side surface, and that is electrically connected to the conductor, the second upper end surface and the second lower end surface being located side by side in the upward direction and the downward direction, the first side surface being connected to the second upper end surface, and an electronic component including an electronic component body and a second electrode, and being located above the insulator, wherein the second upper end surface is covered by the insulator, and the second electrode is electrically connected to the first electrode due to at least a portion of the first side surface being exposed from the insulator.

With circuit modules according to example embodiments of the present invention, it is possible to eliminate a grinding step during manufacturing thereof.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a circuit module 1 according to an example embodiment of the present invention.

FIG. 2 is a cross-sectional view along A-A of a circuit module 1 according to an example embodiment of the present invention.

FIG. 3 is a plan view of an insulator 3 when viewed in an upward direction according to an example embodiment of the present invention.

FIG. 4 is a perspective view of an insulator 3, a first electrode 4L, and a first electrode 4R according to an example embodiment of the present invention.

FIG. 5 is a cross-sectional view along B-B of an insulator 3, a first electrode 4L, and a first electrode 4R according to an example embodiment of the present invention.

FIG. 6 is a perspective view of an electronic component 5 according to an example embodiment of the present invention.

FIG. 7 is a cross-sectional view illustrating an example of a method of manufacturing the circuit module 1 according to an example embodiment of the present invention.

FIG. 8 is a cross-sectional view along A-A of a circuit module 1a according to an example embodiment of the present invention.

FIG. 9 is a cross-sectional view along A-A of a circuit module 1b according to an example embodiment of the present invention.

### DETAILED DESCRIPTION OF THE EXAMPLE EMBODIMENTS

Example embodiments of the present invention will be described in detail below with reference to the drawings.

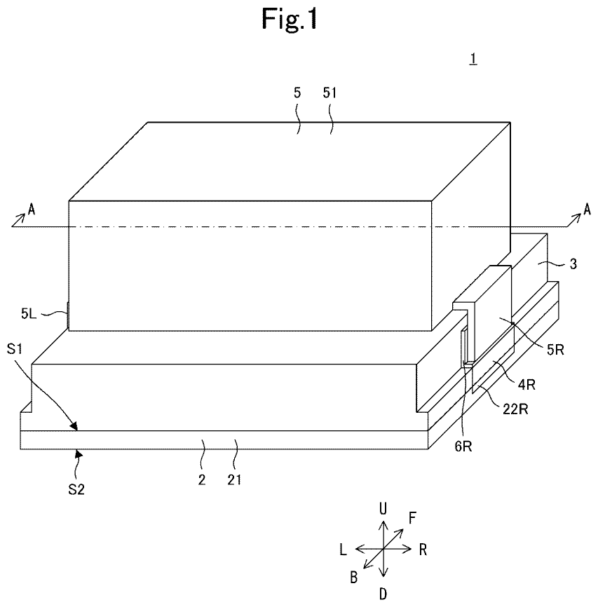

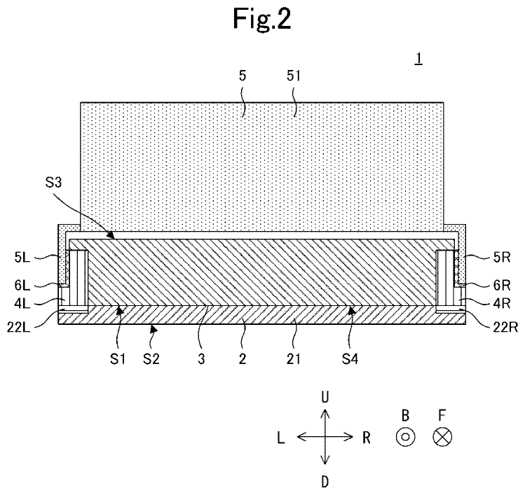

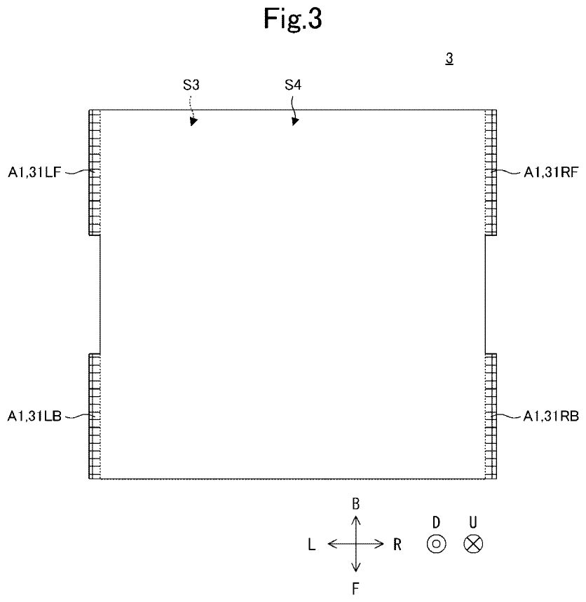

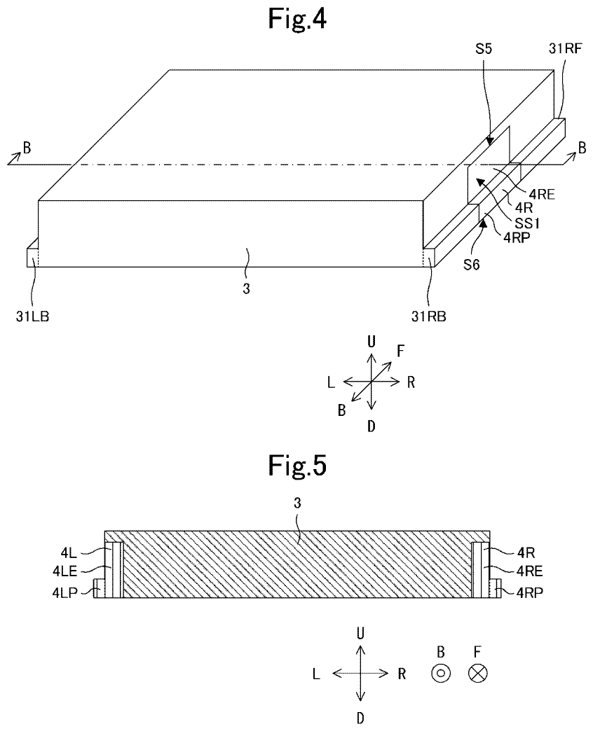

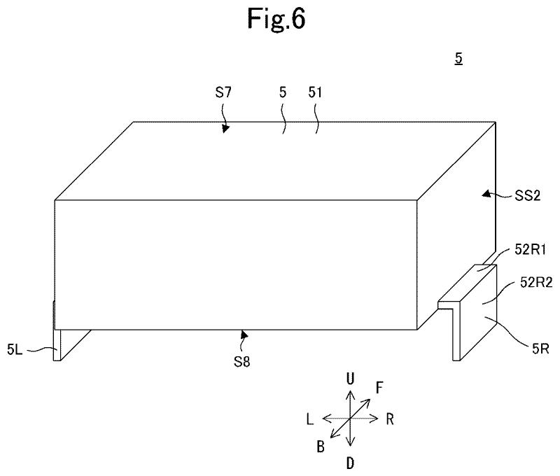

A circuit module 1 according to a first example embodiment of the present invention is described below. FIG. 1 is a perspective view of the circuit module 1. FIG. 2 is a cross-sectional view along A-A of the circuit module 1. FIG. 3 is a plan view of an insulator 3 when viewed in an upward direction. FIG. 4 is a perspective view of the insulator 3, a first electrode 4L, and a first electrode 4R. FIG. 5 is a cross-sectional view along B-B of the insulator 3, the first electrode 4L, and the first electrode 4R. FIG. 6 is a perspective view of an electronic component 5.

In the present description, directions are defined as follows. As shown in FIG. 1, a direction in which a lower end surface S2 and an upper end surface S1 of a circuit board body 21 are situated side by side in this order is defined as an upward direction. A direction opposite to the upward direction is defined as a downward direction. As shown in FIG. 2, a direction in which the first electrode 4L and the first electrode 4R are disposed side by side in this order is defined as a rightward direction. A direction opposite to the rightward direction is defined as a leftward direction. The rightward direction and the leftward direction are orthogonal or substantially orthogonal to the upward direction and the downward direction. A direction that is orthogonal or substantially orthogonal to the upward direction and the rightward direction is defined as a forward direction. A direction opposite to the forward direction is defined as a rearward direction. Directions that are orthogonal or substantially orthogonal to the upward direction and the downward direction are defined as horizontal directions. The rightward direction, the leftward direction, the forward direction, and the rearward direction are each an example of a horizontal direction. However, the upward direction, the downward direction, the rightward direction, the leftward direction, the forward direction, and the rearward direction are directions defined for convenience of explanation, and do not need to be the same as an upward direction, a downward direction, a rightward direction, a leftward direction, a forward direction, and a rearward direction when the circuit module 1 is being used. In each figure, the upward direction and the downward direction may be reversed, the rightward direction and the leftward direction may be reversed, or the forward direction and the rearward direction may be reversed.

In the present description, positional relationships of members are defined as follows. A first member to a third member define the circuit module 1. In the present description, “the first member is disposed on or above the second member” refers to the following state. At least a portion of the first member is positioned directly above the second member. Therefore, when viewed in the upward direction and the downward direction, the first member overlaps the second member. This also definition applies to the directions other than the upward direction.

In the present description, “the first member is disposed above the second member” includes a case in which at least a portion of the first member is positioned directly above the second member and a case in which the first member is not positioned directly above the second member, but the first member is positioned obliquely above the second member. In this case, when viewed in the upward direction and the downward direction, the first member need not overlap the second member. “Obliquely above” refers to, for example, “to the upper left” or “to the upper right”. These definitions also apply to the directions other than the upward direction.

In the present description, unless otherwise specified, each portion of the first member is defined as follows. An upper portion of the first member means the upper half of the first member. An upper end of the first member means an end of the first member in the upward direction. An upper end portion of the first member means the upper end of the first member and the vicinity thereof. These definitions also apply to the directions other than the upward direction.

In the present description, “the first member and the second member are electrically connected to each other” means that there is electrical conduction between the first member and the second member. Therefore, the first member and the second member may directly contact each other, or the first member and the second member need not directly contact each other. When the first member and the second member do not directly contact each other, an electrically conductive third member is disposed between the first member and the second member.

As shown in FIGS. 1 and 2, the circuit module 1 includes a circuit board 2, the insulator 3, the first electrode 4L, the first electrode 4R, the electronic component 5, solder 6L, and solder 6R. In the present example embodiment, the circuit module 1 has a symmetrical or substantially symmetrical structure.

As shown in FIG. 2, the circuit board 2 includes a circuit board body 21, a conductor 22L, and a conductor 22R. In the present example embodiment, the conductor 22L has a structure that is symmetrical or substantially symmetrical with respect to the conductor 22R. Therefore, the conductor 22L is not described. The circuit board 2 includes an upper main surface and a lower main surface that are situated side by side in the upward direction and the downward direction. The upper main surface of the circuit board 2 is positioned above the lower main surface of the circuit board 2. As shown in FIG. 1, the circuit board 2 when viewed in the upward direction and the downward direction has a rectangular or substantially rectangular shape including long sides that extend in the leftward direction and the rightward direction and short sides that extend in the forward direction and the rearward direction.

The circuit board body 21 includes the upper end surface S1 and the lower end surface S2 that are situated side by side in the upward direction and the downward direction. The upper end surface S1 is positioned above the lower end surface S2. Here, the upper end surface S1 is defined as a surface that is positioned at an upper end of the circuit board body 21. This definition also applies to end surfaces other than the upper end surface. In addition, this definition also applies to the members other the circuit board body 21. In the present example embodiment, the circuit board body 21 has a symmetrical or substantially symmetrical structure. Therefore, a left portion of the circuit board body 21 is not described. The upper end surface S1 is a portion of the upper main surface of the circuit board 2. The lower end surface S2 is a portion of the lower main surface of the circuit board 2. An electrical circuit is provided in an inner portion of the circuit board body 21 by using an electrically conductive layer. The circuit board body 21 when viewed in the upward direction and the downward direction has a rectangular or substantially symmetrical shape including long sides that extend in the leftward direction and the rightward direction and short sides that extend in the forward direction and the rearward direction. A right end surface of the circuit board body 21 is a portion of a right surface of the circuit board 2. A front end surface of the circuit board body 21 is the same as a front surface of the circuit board 2. A rear end surface of the circuit board body 21 is the same as a rear surface of the circuit board 2. The upper end surface S1 corresponds to a “first upper end surface”. The lower end surface S2 corresponds to a “first lower end surface”.

The conductor 22R is provided at the circuit board body 21. The conductor 22R is provided at a right end portion of the circuit board body 21. The conductor 22R is electrically conductive. The conductor 22R includes an upper surface and a lower surface that are situated side by side in the upward direction and the downward direction. The upper surface of the conductor 22R is positioned above the lower surface of the conductor 22R. The upper surface of the conductor 22R is a portion of the upper main surface of the circuit board 2. The lower surface of the conductor 22R is positioned above the lower main surface of the circuit board 2. The conductor 22R is electrically connected to the electrical circuit provided in the inner portion of the circuit board body 21. The conductor 22R when viewed in the upward direction and the downward direction has a rectangular or substantially rectangular shape including short sides that extend in the leftward direction and the rightward direction and long sides that extend in the forward direction and the rearward direction. A right surface of the conductor 22R is a portion of the right surface of the circuit board 2. The material of the conductor 22R is, for example, a metal, such as copper.

The insulator 3 has insulating properties. In the present example embodiment, the insulator 3 has a symmetrical or substantially symmetrical structure. The insulator 3 includes an upper end surface S3 and a lower end surface S4 that are situated side by side in the upward direction and the downward direction. The upper end surface S3 is positioned above the lower end surface S4. The insulator 3 is disposed at the upper end surface S1 of the circuit board body 21. In the present example embodiment, the insulator 3 covers the entire or substantially the entire upper end surface S1 of the circuit board body 21. The insulator 3 is made of, for example, resin. The upper end surface S3 and the lower end surface S4 when viewed in the upward direction and the downward direction each have a rectangular or substantially rectangular shape including short sides that extend in the leftward direction and the rightward direction and long sides that extend in the forward direction and the rearward direction. However, in the present example embodiment, as shown in FIG. 3, the lower end surface S4 when viewed in the upward direction and the downward direction has regions A1 that do not overlap the upper end surface S3. The upper end surface S3 corresponds to a “third upper end surface”. The lower end surface S4 corresponds to a “third lower end surface”.

As shown in FIGS. 3 and 4, a protrusion 31RB and a protrusion 31RF are provided on a right end portion of the insulator 3. A protrusion 31LB and a protrusion 31LF are provided on a left end portion of the insulator 3. In the present example embodiment, the protrusion 31LB and the protrusion 31LF each have a structure that is symmetrical or substantially symmetrical with respect to a corresponding one of the protrusion 31RB and the protrusion 31RF. Therefore, the protrusion 31LB and the protrusion 31LF are both not described. The protrusion 31RB and the protrusion 31RF are disposed side by side in this order in the rearward direction. The protrusion 31RB and the protrusion 31RF when viewed in the upward direction and the downward direction are positioned in the regions A1. In other words, by providing the protrusion 31RB and the protrusion 31RF on the right end portion of the insulator 3, the lower end surface S4 includes the regions A1. The protrusion 31RB and the protrusion 31RF when the insulator 3 is viewed in the downward direction are portions of the insulator 3 that are positioned in regions that do not overlap the upper end surface S3. An upper surface of the protrusion 31RB and an upper surface of the protrusion 31RF are not connected to the upper end surface S3. The upper surface of the protrusion 31RB and the upper surface of the protrusion 31RF are positioned between the upper end surface S3 and the lower end surface S4 in the upward direction and the downward direction. On the other hand, a lower surface of the protrusion 31RB and a lower surface of the protrusion 31RF are each a portion of the lower end surface S4.

The first electrode 4L and the first electrode 4R are electrically conductive. In the present example embodiment, the first electrode 4L has a structure that is symmetrical or substantially symmetrical with respect to the first electrode 4R. Therefore, the first electrode 4L is not described. The first electrode 4R is disposed on the conductor 22R. The material of the first electrode 4R is, for example, a metal, such as copper.

The first electrode 4R is provided at the right end portion of the insulator 3. The first electrode 4R includes an upper end surface S5 and a lower end surface S6 that are situated side by side in the upward direction and the downward direction, and a side surface SS1 that is connected to the upper end surface S5. The upper end surface S5 is positioned above the lower end surface S6. As shown in FIGS. 4 and 5, the first electrode 4R includes an electrode portion 4RE and a protrusion 4RP. The electrode portion 4RE has a rectangular or substantially rectangular shape that extends in the upward direction and the downward direction. An upper surface of the electrode portion 4RE is the upper end surface S5. A lower surface of the electrode portion 4RE is a portion of the lower end surface S6. The upper surface of the electrode portion 4RE, by being covered by the insulator 3, is not exposed. That is, the upper end surface S5, by being covered by the insulator 3, is not exposed. On the other hand, the lower surface of the electrode portion 4RE is exposed from the insulator 3. That is, the lower end surface S6 is exposed from the insulator 3. Therefore, the electrode portion 4RE is fixed to the upper surface of the conductor 22R by, for example, solder (not shown). Consequently, the first electrode 4R is electrically connected to the conductor 22R. A right surface of the electrode portion 4RE is exposed from the insulator 3. That is, at least a portion of the side surface SS1 is exposed from the insulator 3. The first electrode 4R is embedded in a right portion of the insulator 3 such that the right surface of the electrode portion 4RE is exposed. The upper end surface S5 corresponds to a “second upper end surface”. The lower end surface S6 corresponds to a “second lower end surface”. The side surface SS1 corresponds to a “first side surface”.

The protrusion 4RP is positioned on the right of the electrode portion 4RE. More specifically, the protrusion 4RP extends in the rightward direction from a lower portion of the electrode portion 4RE. Therefore, the protrusion 4RP when viewed in the upward direction and the downward direction does not overlap the upper end surface S5 of the first electrode 4R. The protrusion 4RP is positioned below the upper end surface S5. An upper surface of the protrusion 4RP is exposed from the insulator 3. A lower surface of the protrusion 4RP is exposed from the insulator 3. Therefore, the protrusion 4RP is fixed to the upper surface of the conductor 22R by, for example, solder (not shown). The right surface of the electrode portion 4RE is exposed from the insulator 3. On the other hand, the protrusion 4RP is positioned between the protrusions 31RB and 31RF of the insulator 3 in the forward direction and the rearward direction. Therefore, a front surface and a rear surface of the protrusion 4RP are both not exposed from the insulator 3.

As shown in FIG. 6, the electronic component 5 includes an electronic component body 51, a second electrode 5L, and a second electrode 5R. The second electrode 5L and the second electrode 5R are electrically conductive. The electronic component 5 is, for example, an inductor. In the present example embodiment, the second electrode 5L has a structure that is symmetrical or substantially symmetrical with respect to the second electrode 5R. Therefore, the second electrode 5L is not described. As shown in FIG. 6, the electronic component body 51 has a rectangular or substantially rectangular parallelepiped shape. Therefore, the electronic component body 51 includes an upper main surface S7 and a lower main surface S8 that are situated side by side in the upward direction and the downward direction, and side surfaces SS2 that connect the upper main surface S7 and the lower main surface S8 to each other. The upper main surface S7 is positioned above the lower main surface S8. As shown in FIG. 1, the electronic component 5 is disposed above the insulator 3. The electronic component body 51 when viewed in the upward direction and the downward direction overlaps the insulator 3. The electronic component body 51 when viewed in the upward direction and the downward direction overlaps the first electrode 4L and the first electrode 4R. As shown in FIG. 2, the lower main surface S8 does not contact the upper end surface S3 of the insulator 3. The side surfaces SS2 each correspond to a “second side surface”.

As shown in FIG. 6, the second electrode 5R is provided at a right end portion of the electronic component body 51. More specifically, the second electrode 5R has a shape that extends in a lower right direction from a right surface of the electronic component body 51. That is, the second electrode 5R has a shape that extends in the lower right direction from at least a portion of the corresponding side surface SS2 of the electronic component body 51. The second electrode 5R includes a first electrode portion 52R1 that extends in the rightward direction from the right surface of the electronic component body 51 and a second electrode portion 52R2 that extends in the downward direction from a right end portion of the first electrode portion 52R1. Therefore, a lower end of the second electrode 5R is positioned below the lower main surface S8 of the electronic component body 51. The second electrode 5R when viewed in the upward direction and the downward direction overlaps the protrusion 4RP of the first electrode 4R. The material of the second electrode 5R is, for example, a metal, such as copper. The second electrode portion 52R2 corresponds to an “electrode portion”.

As shown in FIGS. 1 and 2, the electronic component 5 is fixed to the first electrode 4L and the first electrode 4R by the solder 6L and the solder 6R. In the present example embodiment, the solder 6L is symmetrical or substantially symmetrical with respect to the solder 6R. Therefore, the solder 6L is not described. The solder 6R is provided between the first electrode 4R and the second electrode 5R. More specifically, the solder 6R is positioned between the right surface of the electrode portion 4RE and a left surface of the second electrode portion 52R2, and contacts the right surface of the electrode portion 4RE and the left surface of the second electrode portion 52R2. Therefore, the solder 6R fixes the left surface of the second electrode portion 52R2 to the right of the right surface of the electrode portion 4RE. The solder 6R is positioned between the upper surface of the protrusion 4RP and a lower surface of the second electrode portion 52R2, and contacts the upper surface of the protrusion 4RP and the lower surface of the second electrode portion 52R2. Therefore, the solder 6R fixes the lower surface of the second electrode portion 52R2 onto the upper surface of the protrusion 4RP. That is, by exposing the right surface of the electrode portion 4RE of the first electrode 4R from the insulator 3, the second electrode 5R is electrically connected to the first electrode 4R. Therefore, the second electrode 5R is electrically connected to the conductor 22R.

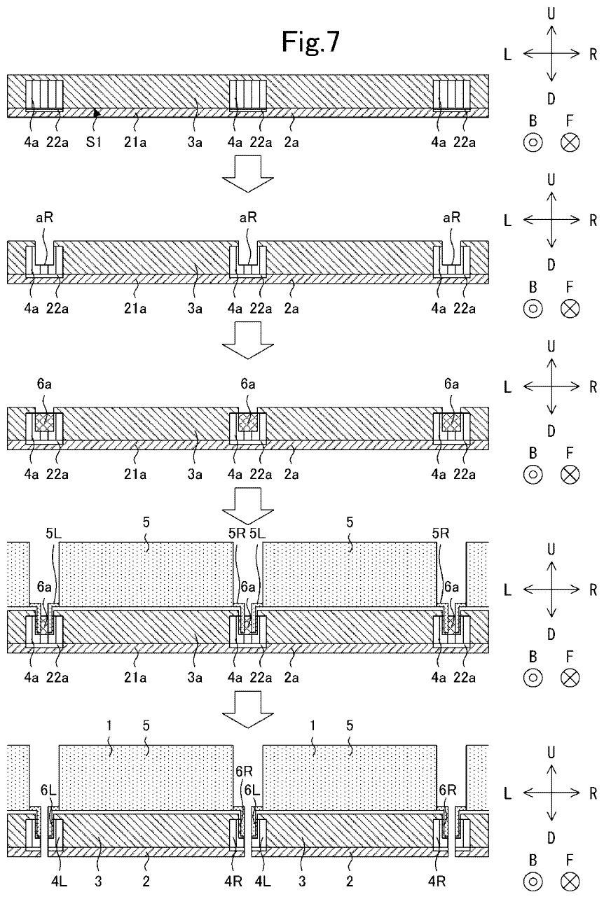

Next, an example of a method of manufacturing the circuit module 1 according to an example embodiment of the present invention is described with reference to the drawings. FIG. 7 is a cross-sectional view illustrating an example of the method of manufacturing the circuit module 1.

First, a circuit board 2a, where a plurality of conductors 22a are provided at an upper end surface S1 of a circuit board body 21, an insulator 3a, and a plurality of electrodes 4a are prepared. Solder pastes (not shown) are applied to upper surfaces of the respective conductors 22a. At this time, the plurality of conductors 22a are disposed side by side in the leftward direction and the rightward direction. The plurality of electrodes 4a are disposed side by side in the leftward direction and the rightward direction. The insulator 3a is disposed on the circuit board 2a. The plurality of electrodes 4a are each disposed on a corresponding one of the plurality of conductors 22a.

Next, the insulator 3a and the plurality of electrodes 4a are half-cut. More specifically, when viewed in the upward direction and the downward direction, the plurality of electrodes 4a and the insulator 3a are cut such that, in regions that overlap the respective electrodes 4a, regions including entire or substantially entire outer edges of upper surfaces of the respective electrodes 4a, and lower edge portions of the respective electrodes 4a remain. This causes a plurality of concave portions aR to be formed.

Next, the plurality of concave portions aR are filled with solder pastes 6a. The positions of upper ends of the respective solder pastes 6a in the upward direction and the downward direction are aligned with the positions of upper ends of the respective electrodes 4a in the upward direction and the downward direction. The upper ends of the respective solder pastes 6a may be positioned below the upper ends of the respective electrodes 4a.

Next, a plurality of electronic components 5 are disposed on the insulator 3 such that second electrodes 5L and second electrodes 5R are each inserted into a corresponding one of the solder pastes 6a. Thereafter, the circuit board 2a, the insulator 3a, the plurality of electrodes 4a, the plurality of electronic components 5, and the solder pastes 6a are placed in a reflow furnace and are heated. This causes the plurality of solder pastes 6a to be fused. Thereafter, the circuit board 2a, the insulator 3a, the plurality of electrodes 4a, the plurality of electronic components 5, and the solder pastes 6a are removed from the reflow furnace and are naturally cooled. As a result, the fused plurality of solder pastes 6a are solidified. This causes the plurality of solder pastes 6a to fix the second electrodes 5L and the second electrodes 5R.

Next, the circuit board 2a, the insulator 3a, and the plurality of solder pastes 6a are fully cut. More specifically, the circuit board 2a, the insulator 3a, and the plurality of solder pastes 6a are each cut at a region between, in the leftward direction and the rightward direction, the second electrode 5R of a certain electronic component 5 and the second electrode 5L of another electronic component 5 adjacently disposed on the right of the certain electronic component 5. This causes the circuit board 2a, the insulator 3a, and the plurality of solder pastes 6a to be divided. As a result, each circuit module 1 is completed.

According to each circuit module 1, it is possible to eliminate a grinding step at the time of manufacturing. More specifically, an upper end surface S5 of the first electrode 4R is covered by the insulator 3. Therefore, the upper end surface S5 of the first electrode 4R is not exposed from the insulator 3. On the other hand, at least a portion of a side surface SS1 of the first electrode 4R is exposed from the insulator 3. At the time of the manufacturing of each circuit module 1, at least a portion of the side surface SS1 of the first electrode 4R can be exposed from the insulator 3 by half-cutting the insulator 3a and the electrode 4a. This makes it possible to electrically connect the first electrode 4R and the second electrode 5R to each other. Therefore, according to each circuit module 1, a grinding step of exposing the first electrode 4R from the insulator 3 by grinding the insulator 3 can be eliminated.

According to each circuit module 1, it is possible to easily increase heat dissipation of the first electrode. More specifically, at least a portion of the side surface SS1 of the first electrode 4R is exposed from the insulator 3. Therefore, the area of a portion of the first electrode 4R that is exposed from the insulator 3 can be easily made larger than the area of a portion of the first electrode that is exposed from the insulator when an upper end surface of the first electrode is exposed from the insulator. In addition, a reduction in the heat dissipation of the first electrode 4R can be reduced or prevented by the electronic component body 51. As a result, according to each circuit module 1, it is possible to easily increase the heat dissipation of the first electrode.

According to each circuit module 1, it is possible to reduce the size of each circuit module. More specifically, the electronic component body 51 when viewed in the upward direction and the downward direction overlaps the first electrode 4L and the first electrode 4R. Therefore, the length of each circuit module 1 in the leftward direction and the rightward direction can be made shorter than the length of each circuit module in the leftward direction and the rightward direction where the electronic component body does not overlap the first electrode when viewed in the upward direction and the downward direction. As a result, according to each circuit module 1, it is possible to reduce the size of each circuit module.

According to each circuit module 1, it is possible to reduce or prevent displacement of the position of the electronic component 5. More specifically, when the upper end surface of the first electrode is exposed from the insulator, solder paste is applied to the upper end surface of the first electrode, and the second electrode of the electronic component is mounted on the solder paste. Thereafter, the position of the second electrode may be displaced when the solder paste is fused due to the heating and the second electrode slides on the solder paste. On the other hand, according to each circuit module 1, at least a portion of the side surface SS1 of the first electrode 4R is exposed from the insulator 3. A lower end of the second electrode 5R is positioned below a lower main surface S8 of the electronic component body 51. This causes the second electrode 5R to be electrically connected to the first electrode 4R. The solder paste 6a is positioned between a right surface of an electrode portion 4RE of the first electrode 4R and a left surface of a second electrode portion 52R2 of the second electrode 5R. Therefore, the displacement of the position of the second electrode 5R due to the sliding of the second electrode 5R on the solder paste 6a can be reduced or prevented from occurring. As a result, according to each circuit module 1, it is possible to reduce or prevent the displacement of the position of the electronic component 5.

According to each circuit module 1, it is possible to easily position the electronic component 5. More specifically, the second electrode 5R when viewed in the upward direction and the downward direction overlaps a protrusion 4RP of the first electrode 4R. It is possible to position the electronic component 5 by disposing the electronic component 5 such that the second electrode 5R when viewed in the upward direction and the downward direction overlaps the protrusion 4RP of the first electrode 4R. Therefore, according to each circuit module 1, it is possible to easily position the electronic component 5.

According to each circuit module 1, since the first electrode 4R includes the protrusion 4RP extending in the rightward direction, it is possible to stop solder 6R on the protrusion 4RP of the first electrode 4R.

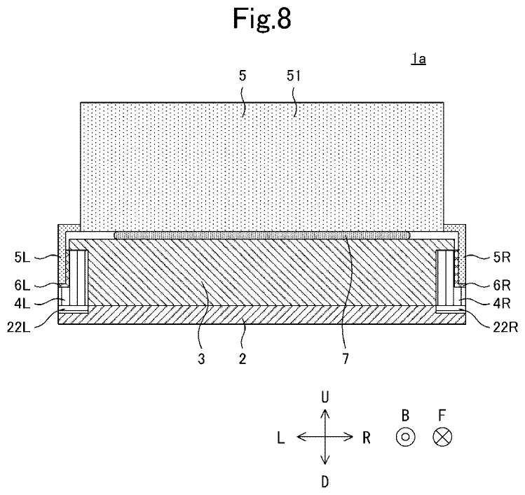

A structure of a circuit module 1a according Modification 1 of an example embodiment of the present invention is described below with reference to the drawings. FIG. 8 is a cross-sectional view along A-A of the circuit module 1a. With regard to the circuit module 1a according to Modification 1, only portions that differ from those of the circuit module 1 according to the first example embodiment are described and the remainder is not described.

The circuit module 1a differs from the circuit module 1 in further including an adhesive layer 7.

As shown in FIG. 8, the adhesive layer 7 is provided between the electronic component 5 and the insulator 3 in the forward direction and the rearward direction. More specifically, the adhesive layer 7 is provided between the upper end surface S3 of the insulator 3 and the lower main surface S8 of the electronic component body 51. The adhesive layer 7 fixes the electronic component 5 onto the insulator 3. The adhesive layer 7 may be electrically conductive or may have insulating properties.

Even the circuit module 1a described above provides the same or substantially the same advantageous effects as the circuit module 1. According to the circuit module 1a, it is possible to increase the area of application of the adhesive layer and to reduce or prevent the adhesive layer from contacting the solder. More specifically, the adhesive layer 7 is provided between the upper end surface S3 of the insulator 3 and the lower main surface S8 of the electronic component body 51. On the other hand, in the circuit module 1a, solder does not exist between the upper end surface S3 of the insulator 3 and the lower main surface S8 of the electronic component body 51. Therefore, it is possible to increase the area of application of the adhesive layer 7. Consequently, it is possible to firmly fix the electronic component 5 onto the insulator 3. Even if the area of application of the adhesive layer 7 is increased, since solder does not exist between the upper end surface S3 of the insulator 3 and the lower main surface S8 of the electronic component body 51, the adhesive layer 7 is unlikely to contact the solder 6L and the solder 6R. Therefore, it is possible to reduce or prevent the adhesive layer 7 from contacting the solder 6L and the solder 6R. As a result, according to the circuit module 1a, it is possible to increase the area of application of the adhesive layer and to reduce or prevent the adhesive layer from contacting the solder.

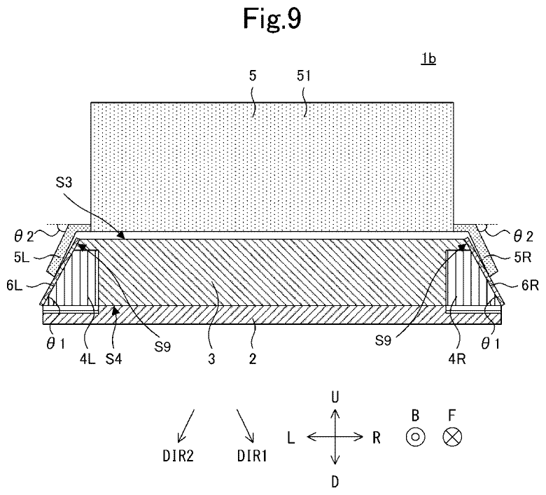

A structure of a circuit module 1b according Modification 2 of an example embodiment of the present invention is described below with reference to the drawings. FIG. 9 is a cross-sectional view along A-A of the circuit module 1b. With regard to the circuit module 1b according to Modification 2, only portions that differ from those of the circuit module 1 according to the first example embodiment are described and the remainder is not described.

The circuit module 1b differs from the circuit module 1 in that a protrusion 31RB and a protrusion 31RF are not provided on the right end portion of the insulator 3, in that a protrusion 31LB and a protrusion 31LF are not provided on the left end portion of the insulator 3, in that, in the upward direction and the downward direction, the insulator 3 has an oblique surface S9 that is positioned between the upper end surface S3 and the lower end surface S4, in that the first electrode 4L includes a second electrode portion 52L2 that extends in a second direction DIR2 from a left end portion of a first electrode portion 52L1, and in that the first electrode 4R includes a second electrode portion 52R2 that extends in a first direction DIR1 from a right end portion of a first electrode portion 52R1.

The insulator 3 has a truncated square pyramid shape including the upper end surface S3 as an upper base and the lower end surface S4 as a lower base. As shown in FIG. 9, the insulator 3 includes the oblique surface S9 that is positioned between the upper end surface S3 and the lower end surface S4 in the upward direction and the downward direction. More specifically, when viewed in the forward direction and the rearward direction, an angle θ1 between the oblique surface S9 and the lower end surface S4 is, for example, greater than about 0 degrees and less than about 90 degrees.

The second electrode portion 52R2 extends in the first direction DIR1 from the right end portion of the first electrode portion 52R1. The first direction DIR1 is a direction including a downward direction component and differing from the downward direction. Specifically, the first direction DIR1 is a lower right direction. When viewed in the forward direction and the rearward direction, as angles between the first direction DIR1 and the leftward direction and the rightward direction, there are two angles, an acute angle and an obtuse angle. Of these angles, the acute angle is an angle θ2 between the first direction DIR1 and the leftward direction and the rightward direction. When viewed in the forward direction and the rearward direction, the angle θ2 between the first direction DIR1 and the leftward direction and the rightward direction is larger than the angle θ1 between the oblique surface S9 and the lower end surface S4, and is less than about 90 degrees. Therefore, the solder 6R fixes a left surface of the second electrode portion 52R2 to an upper right portion of the oblique surface S9.

Even the circuit module 1b described above provides the same or substantially the same advantageous effects as the circuit module 1. According to the circuit module 1b, it is possible to easily electrically connect the first electrode 4R and the second electrode 5R to each other. More specifically, when viewed in the forward direction and the rearward direction, the angle θ1 between the oblique surface S9 and the lower end surface S4 is greater than about 0 degrees and less than about 90 degrees. When viewed in the forward direction and the rearward direction, the angle θ2 between the first direction DIR1 in which the second electrode portion 52R2 extends and the leftward direction and the rightward direction is larger than the angle θ1 between the oblique surface S9 and the lower end surface S4, and is less than about 90 degrees. Since, when viewed in the forward direction and the rearward direction, the angle θ2 between the first direction DIR1 and the leftward direction and the rightward direction is larger than the angle θ1 between the oblique surface S9 and the lower end surface S4, the second electrode portion 52R2 and the solder 6R are likely to contact each other and the second electrode 5R and the first electrode 4R are likely to be electrically connected to each other. Since, when viewed in the forward direction and the rearward direction, the angle θ2 between the first direction DIR1 and the leftward direction and the rightward direction is less than about 90 degrees, it is possible to increase the contact area between the second electrode 5R and the solder 6R. Therefore, it is possible to more reliably connect the first electrode 4R and the second electrode 5R to each other. As a result, according to the circuit module 1b, it is possible to easily electrically connect the first electrode 4R and the second electrode 5R to each other.

The circuit module according to the present invention is not limited to the circuit module 1, the circuit module 1a, and the circuit module 1b according to example embodiments and modifications thereof, and can be modified within the scope and gist thereof. The structures of the circuit module 1, the circuit module 1a, and the circuit module 1b may be combined in any combination.

The circuit module 1, the circuit module 1a, and the circuit module 1b need not have a symmetrical or substantially symmetrical structure.

The conductor 22L need not have a structure that is symmetrical or substantially symmetrical with respect to the conductor 22R.

The circuit board body 21 need not have a symmetrical or substantially symmetrical structure.

The insulator 3 need not have a symmetrical or substantially symmetrical structure.

The protrusion 31LB and the protrusion 31LF need not have structures that are symmetrical or substantially symmetrical with respect to the protrusion 31RB and the protrusion 31RF, respectively.

The first electrode 4L need not have a structure that is symmetrical or substantially symmetrical with respect to the first electrode 4R.

The second electrode 5L need not have a structure that is symmetrical or substantially symmetrical with respect to the second electrode 5R.

The solder 6L need not have a symmetrical or substantially symmetrical with respect to the solder 6R.

The solder 6L and the solder 6R are not structural elements that are necessary.

The protrusion 31RB, the protrusion 31RF, the protrusion 31LB, and the protrusion 31LF are not structural elements that are necessary. The protrusion 4RP is also not a structural element that is necessary.

In the upward direction and the downward direction, the lower surface of the protrusion 31RB and the lower surface of the protrusion 31RF may be positioned between the upper end surface S3 and the lower end surface S4 of the insulator 3.

The lower end surface S4 when viewed in the upward direction and the downward direction need not have the regions A1 that do not overlap the upper end surface S3.

The electronic component body 51 when viewed in the upward direction and the downward direction need not overlap the first electrode 4L and the first electrode 4R.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit module comprising:
a circuit board including a circuit board body and a conductor, the circuit board body including a first upper end surface and a first lower end surface located side by side in an upward direction and a downward direction, the conductor being located at the circuit board body;
an insulator located at the first upper end surface;
a first electrode including a second upper end surface, a second lower end surface, and a first side surface, and electrically connected to the conductor, the second upper end surface and the second lower end surface being located side by side in the upward direction and the downward direction, the first side surface being connected to the second upper end surface; and
an electronic component including an electronic component body and a second electrode, and being located above the insulator; wherein
the second upper end surface is covered by the insulator; and
the second electrode is electrically connected to the first electrode due to at least a portion of the first side surface being exposed from the insulator.

2. The circuit module according to claim 1, wherein the electronic component body when viewed in the upward direction and the downward direction overlaps the first electrode.

3. The circuit module according to claim 1, wherein
the electronic component body includes an upper main surface, a lower main surface, and a second side surface, the upper main surface and the lower main surface being located side by side in the upward direction and the downward direction, the second side surface connecting the upper main surface and the lower main surface to each other;
the second electrode extends from at least a portion of the second side surface; and
a lower end of the second electrode is positioned below the lower main surface.

4. The circuit module according to claim 1, further comprising:
an adhesive layer; wherein
the insulator includes a third upper end surface and a third lower end surface located side by side in the upward direction and the downward direction;
the electronic component body includes an upper main surface and a lower main surface located side by side in the upward direction and the downward direction; and
the adhesive layer is provided between the third upper end surface and the lower main surface.

5. The circuit module according to claim 1, wherein
the first electrode includes a protrusion extending in a horizontal direction orthogonal or substantially orthogonal to the upward direction and the downward direction;
the protrusion is located below the second upper end surface; and
the second electrode when viewed in the upward direction and the downward direction overlaps the protrusion.

6. The circuit module according to claim 1, wherein
the insulator includes a third upper end surface, a third lower end surface, and an oblique surface, the third upper end surface and the third lower end surface being located side by side in the upward direction and the downward direction, the oblique surface being positioned between the third upper end surface and the third lower end surface in the upward direction and the downward direction;
the second electrode includes an electrode portion extending in a first direction including a downward direction component and differing from the downward direction;
when viewed in a forward direction and a rearward direction orthogonal or substantially orthogonal to the upward direction and the downward direction, an angle between the oblique surface and the third lower end surface is greater than about 0 degrees and less than about 90 degrees; and
when viewed in the forward direction and the rearward direction, an acute angle between angles in the first direction and a leftward direction and a rightward direction orthogonal or substantially orthogonal to the upward direction and the downward direction and to the forward direction and the rearward direction is larger than the angle between the oblique surface and the third lower end surface and is less than about 90 degrees.

7. The circuit module according to claim 1, wherein the electronic component is an inductor.

8. The circuit module according to claim 1, wherein the insulator is made of resin.

9. The circuit module according to claim 1, wherein the circuit board has a rectangular or substantially rectangular shape in the upward and downward direction.

10. The circuit module according to claim 1, wherein the conductor includes copper.

11. The circuit module according to claim 1, wherein the first electrode includes copper.

12. The circuit module according to claim 1, wherein the electronic component has a rectangular or substantially rectangular shape.

13. The circuit module according to claim 1, wherein the second electrode includes copper.

14. The circuit module according to claim 4, wherein the adhesive layer includes an electrically conductive material.

15. The circuit module according to claim 4, wherein the adhesive layer includes an insulating material.

16. The circuit module according to claim 1, wherein the insulator has a truncated square pyramid shape.
